(19) United States
(12) Patent Application Publication
(10) Pub. No.: US 2022/0002171 A1
(43) Pub. Date: Jan. 6, 2022

(54) ELECTRODE HOLDER FOR PURIFYING WATER AND FLOATING DEVICE THAT COMPRISES SAME

(71) Applicant: AMBIENTE SOLUCIONES S.A.S., Medellin (CO)

(72) Inventors: Diego Luis CORREA SALAS, Medellin (CO); Faber Alberto DIAZ OSPINA, Medellin (CO)

(21) Appl. No.: 17/289,906

(22) PCT Filed: Jul. 3, 2019
(86) PCT No.: PCT/IB2019/055656

§ 371 Date: Apr. 29, 2021

(30) Foreign Application Priority Data
Aug. 9, 2018 (CO) NC2018/0008376

(51) Int. Cl. C02F 1/467; C02F 1/461

(52) U.S. Cl. CPC C02F 1/467; C02F 2001/46133; C02F 1/46109

(57) ABSTRACT

The present application relates to an electrode holder and a floating device that comprises same for purifying bodies of water. The electrode holder comprises a base, a metal fastener and a cover. A plurality of electrodes are embedded in the metal fastener, housed inside the base and under the cover. The electrodes can be made of copper, zinc, silver, gold, stainless steel or combinations thereof. The metal fastener can be connected to any electric power source. The flow of electric energy towards the electrodes that are in contact with the water generates an oxidation-reduction reaction, releasing ions, which have a purifying effect, into the water. The device which comprises this electrode holder also comprises a photovoltaic module, an energy storage module that serves as an electric power source for the electrodes, a pH meter and an external structure.

### TECHNICAL FIELD

The present invention belongs to the technical field of water purification, specifically, to that carried out by releasing ions into water in order to obtain a purifying effect through the electrolytic effect on different types of composite metal alloys, with nanotechnological and purifying effect.

### BACKGROUND ART

Nowadays, water bodies are widely used for many purposes, one of the most common is for recreational purposes, such as swimming pools, which are used by people in different climates. However, water bodies must be constantly maintained in order to avoid becoming a center for spreading diseases, since stagnant or still water accelerates the proliferation of algae, bacteria and other microorganisms, as well as the spread of pests, which may affect human and animal health.

In this sense, all water bodies must be treated and must have a recirculation system allowing the water to be in movement and not stagnate, avoiding the production of these algae and/or microorganisms. The most commonly used way to assist in this water purification process is through the use of chlorine, which allows disinfection of the water body and is relatively harmful to human health.

It has been found that the use of chlorine in water bodies may be harmful to humans, as it may cause allergies on the skin and/or other body parts coming into direct contact with water, such as the eyes. Chlorine also causes hair damage, and generates certain long-term effects, such as damage to the ozone layer, as it evaporates and becomes a greenhouse gas. In addition, chlorine damages and discolors clothing and generates calcium buildup or incrustations in pipes and in the physical structures supporting water bodies, causing expenses and maintenance costs. Therefore, there are alternatives in the prior art allowing water disinfection, looking for fewer side effects.

Document US 20020078990 teaches a floating disinfectant apparatus employing a plurality of electrodes to contact a water body in order to obtain a nearly maintenance-free disinfectant chemical generator, wherein the disinfectant chemical is chlorine and said chlorine is generated by an electrolytic process. Thus, the electrolytic reaction may be energized by photovoltaic cells, making the device self-contained and capable of floating freely within a water body. Also, the energy source is channeled through a polarity reversal module, which alternates the direction of the current generated by the photovoltaic cells at a predetermined time interval, wherein such polarity reversal reduces scale buildup and prevents corrosion of the metal electrodes.

On the other hand, KR101383816 (B1) relates to a multi-contact type electrode structure for underwater electrolysis and an apparatus for sterilizing water using the structure. The apparatus for sterilizing water includes an electrode structure including a first electrode, comprising a base and multiple rod-shaped electrodes, and a second electrode that is located perpendicular to the rod-shaped electrodes, and has holes to insert the rods, wherein multiple underwater discharge points are created. The purpose of this electrode structure is to generate underwater electrolysis between an anode and a cathode and, thus, obtain water purification.

Application FR2709430 (A1) mentions an electrode holder device for swimming pool filtration, which has an electrically insulating cover and metal terminals connected to the electric current to which copper and silver electrodes are screwed. The lower part of the device is connected to a pipe allowing water inlet and outlet.

### BRIEF DESCRIPTION OF THE INVENTION

The inventors have identified in the technical field the need for new alternative devices, allowing to perform a purification process of water bodies, which do not require or use the least possible amount of chemicals which may become uncomfortable or harmful to health, but allowing to obtain high levels of purity. Moreover, the inventors have identified the need for devices that may operate autonomously and which are easy to implement in water bodies, by having autonomous energy sources (renewable energy source, for example, solar energy) for carrying out the adequate purification and without the need for cables or electrical connections. Furthermore, it has been identified the need for purification devices which do not require constant maintenance and when it is necessary to be carried out, the maintenance is easy. Moreover, the inventors identified the need for devices that do not require removal from water bodies, when a human or animal comes into contact with the water being treated. In addition, there is a need for devices that may be reused over a long period of time, and thus have an extended shelf life.

Thus, the inventors of the present application provide an electrode holder and a device comprising the same, solving some of the needs mentioned herein.

The electrode holder comprises a base, a metal holder and a cover. Embedded in the metallic holder is a plurality of electrodes which are housed within the base and under the cover. The electrodes may be of any material known in the technical field for the manufacture of electrodes, such as for example copper, zinc, silver, gold, stainless-steel and combinations thereof. The metal holder may be connected to any electrical power source. The electrode holder may be immersed in the water body to be purified. The water flows into the electrode holder through holes in the base and cover, coming into contact with the electrodes embedded in the metal holder, which in turn is connected to an electrical power source. The flow of electrical energy to the electrodes in contact with the water, generates an oxidation-reduction reaction releasing ions, which have a purifying effect, into the water.

The floating device comprising the electrode holder has a monoblock construction, being smooth and impermeable, in one piece, which prevents the incrustation of molds, bacteria or residues. This device allows the purification of industrial and/or recreational waters by means of metallic multi-electrodes releasing ions and/or minerals by means of electric currents induced by a photovoltaic panel, thus obtaining different metallic ionic mixtures and/or particulate minerals for different physicochemical purposes in the water. The device of the invention also has an accessory that measures the pH of water, in order to keep a permanent control over the treatment carried out.

Thus, the floating ionic purifying device of the present invention is composed of a photovoltaic module, which receives energy from the sun and which, according to its size or voltage and current generation capacity, may variably energize the electrodes through the holder of the electrode holder and produce different sizes of ionic and/or mineral particles according to the voltage, a light indicator that shows the status of the device at all times, an energy storage unit that allows to store the energy obtained through the photovoltaic module and thus keep it for later use either day or night, the electrode holder described above housing electrodes that come into contact with water for the release of ions and/or minerals to the purification of water and a pH meter are thus carried out.

In preferred embodiments of the present invention, electrodes contacting water for the release of ions and/or minerals are made of materials selected from the group comprising copper, zinc, silver, gold and a special water softening electrode, provided with a copper core and stainless-steel coating, or combinations thereof.

Thus, the present invention allows to obtain an advantage over similar elements or devices existing in the prior art, since it provides an electrode holder and a device involving and combining minerals and metals in their proper ratio, in parts per million, allowing to remain in the water body without the need to be removed by not contaminating and not affecting human or animal health. The light emitting diode (LED) of the floating device allows to display and indicate the device status to the user at all times and provides a resistive load, allowing to control the current flow and thus to obtain nano sizes of ionic particles and other effects derived from the chromatic spectrum, through the wavelength. Both the electrode holder and the floating device comprising it are simple to manufacture, economical, compact and do not require a large amount of space to obtain the purification of a large water body, while its operation is based on the consumption of electrodes for water ionization, thus reducing the use of chlorine or chemical elements in the water body to be treated. Finally, they are totally safe for humans and should not be removed when in direct contact with water, for example, in the case of recreational waters, such as a swimming pool.

Additionally, the electrode holder structure, particularly of the metal holder housing the cylindrical electrodes, makes it possible to combine different electrodes of different materials to obtain a combination of ions in the water, having an improved purifying activity.

Furthermore, the structure of the purifying device allows the electrode holder to be easily removed and replaced when the electrodes have worn out, making the lifetime of the rest of the floating device longer, by allowing its reuse.

### BRIEF DESCRIPTION OF THE FIGURES

The present invention is more clearly understood from the following figures, where the components associated with the present electrode holder are shown, as well as novel elements with respect to the prior art, wherein the figures are not intended to limit the invention scope, which is given solely by the appended claims, wherein:

FIG. 1 corresponds to a perspective view in a preferred embodiment of the purifying device in the present invention.

FIG. 2 corresponds to an exploded view in a preferred embodiment of the FIG. 1 purifying device, wherein all internal elements thereof are shown.

FIG. 3 corresponds to a planar top view in a preferred embodiment of the FIG. 1 purifying device.

FIG. 4 corresponds to a planar side view in a preferred embodiment of the FIG. 1 purifying device.

FIG. 5 corresponds to a bottom perspective view in a preferred embodiment of the FIG. 1 purifying device, wherein the coupling of the electrode holder element to the main body is shown.

FIG. 6 corresponds to a top perspective view in a preferred embodiment of the electrode holder base.

FIG. 7 corresponds to a top perspective view in a preferred embodiment of the metal electrode holder.

FIG. 8 corresponds to a top perspective view of the cover in a preferred embodiment of the electrode holder.

FIG. 9 corresponds to an exploded view in a preferred embodiment of the electrode holder, wherein the internal elements of the electrode holder are shown.

FIG. 10 corresponds to a top perspective view in a preferred embodiment of the electrode holder.

FIG. 11 corresponds to a bottom view in a preferred embodiment of the purifying device in the invention.

### DETAILED DESCRIPTION OF THE INVENTION

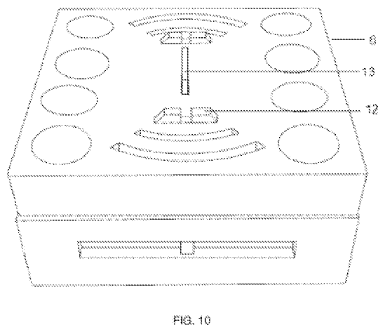

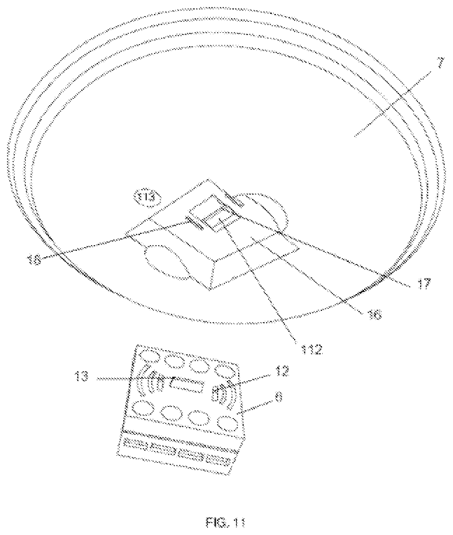

In a first aspect the present invention relates to an electrode holder (6) comprising a base (8), a metal holder (9) and a cover (10), as illustrated in FIG. 9 and FIG. 10.

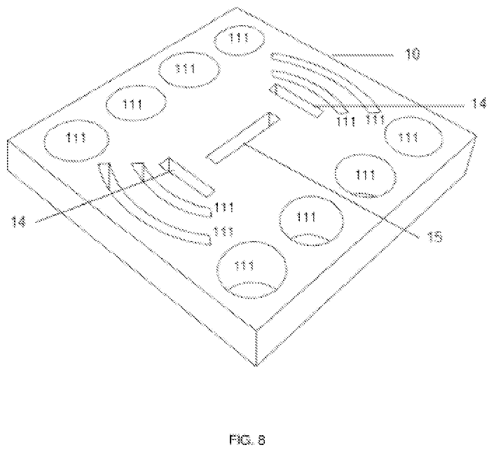

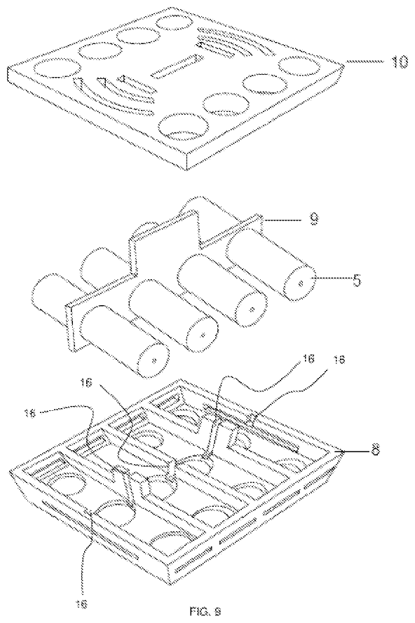

The metal holder (9) illustrated in FIG. 7 has a rectangular shape with a plurality of holes (109). Through each hole (109) an electrode (110) is embedded under pressure. In addition, the holder (9) has a tab (13) in the central part which protrudes towards the top of the holder and engages with a slot (15) in the cover (10). Preferably, the electrodes (110) that are embedded in the metal holder (9) may be in the form of an AA or AAA battery. The electrodes may preferably have a cylindrical shape, in which case the holes in the metal holder are circular.

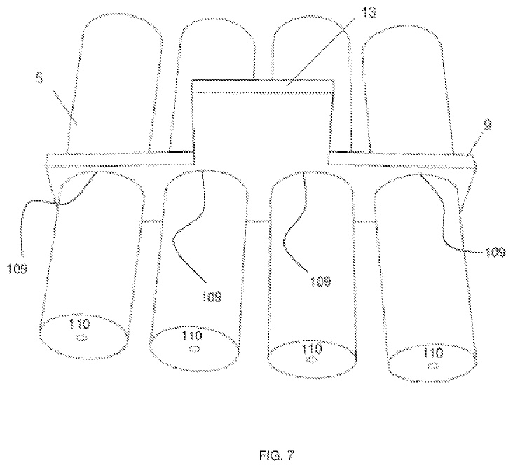

The base (8) is disposed at the bottom of the electrode holder (6), and comprises five walls including a front wall (101), an opposite rear wall (102), a right wall (103), an opposite left wall (104), and a bottom wall (105), as illustrated in FIG. 6. In the cavity formed by the walls, divisions (11) are arranged parallel to the right (103) and opposite left (104) walls, forming a plurality of channels, each receiving one of the electrodes (5) which are embedded in the metal holder (9).

As may be seen in FIG. 6, each of the right wall (103) and left wall (104) of the base (8) have holes (106) from end to end, through which water flows into the electrode holder interior, coming into contact with the electrodes which are housed in the base channels. Moreover, the front wall (101) and the opposite rear wall (102) are provided with holes (107) which are arranged across the width of each of the plurality of channels, through which water also flows into the interior of the electrode holder, coming into contact with the electrodes housed in the channels of the base (8). Holes (108) are arranged in the bottom wall (105) along the base of channels, which moreover allow water to enter the electrode holder and come into contact with the electrodes (110).

In the base (8), in the central area of each of the divisions (11), and of the opposite right wall (103) and left wall (104), a perpendicular cavity (16) is arranged, wherein the metal holder (9) that houses a plurality of electrodes fits, and, therefore, each electrode (5) is located in one of the channels, as seen in FIG. 9. Also, some of the divisions (11) may comprise tabs (12), which protrude towards the top of the base (8), and which engage with slots in the cover (10) of the electrode holder.

The cover (10) is disposed on the top of the electrode holder (6), and comprises a plurality of holes (111) through which water flows. These holes may be circular, curved or of any other suitable geometry, allowing the water to flow into the interior of the electrode holder to come into contact with the electrodes. In addition, the cover (10) comprises slots (14) into which the tabs (12) of the base (8) fit, and the slot (15) into which the tab (13) of the holder (9) fits. Thus, the base (8), the holder (9) and the cover (10), fit together configuring the electrode holder (6), as exemplified in FIG. 10.

The metal holder tab contacts the negative pole of an electrical energy source, such as an energy storage module, an energy generator module, or a battery, connecting the electrodes that are in contact with water to this negative pole. The positive pole of the energy source is connected to a metallic element which is also in contact with the water. As a result of the flow of electrical energy generated by these connections, an oxidation-reduction reaction takes place releasing ions or minerals from the electrodes into the water. In this way, the electrode holder may be put in contact with any water body and with any source of electrical energy, in order to start producing the reaction that releases ions with purifying action to the water to be treated.

The present invention is based on the principle of a general reaction named water simple electrolysis, which consists of galvanic pairs with positive and negative electrical conditions that generate ions dispersed in the water, which depending on the metal and/or mineral used, generates positive or negative charges creating different effects such as algaecide flocculant and ionizing antibacterial, antiviral and fungicide purification.

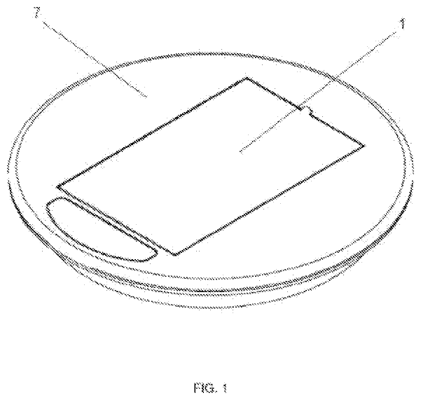

In a second aspect, the invention is directed to a floating, smooth, waterproof device comprising the electrode holder previously described and exemplified in FIG. 1 and FIG. 11. This device is a water purifier using ion release by solar-induced electrical currents, thus obtaining different metallic and/or mineral ionic mixtures for different physicochemical purposes in water.

Thus, the purifying device of the present invention is composed of or comprises the following components or parts that make it different from existing devices in the prior art: a photovoltaic module (1), which is composed of a photovoltaic panel, preferably of 5 V 300 mA, either polycrystalline or monocrystalline, of varying size wherein said photovoltaic module (1) has different powers, voltages and currents, preferably 5, has a cell efficiency of approximately 18%, and the device has an average weight of 1 g, which makes it suitable to be placed on top of any type of water body; one or several luminous indicator elements (2), which allows to show and indicate the device status to the user at all times and provides a resistive load allowing to control the current flow, in order to obtain nano sizes of ionic particles and other effects derived from the chromatic spectrum, where said indicator (2) is of Light Emitting Diode (LED) type, such as a diode of any color and wavelength, preferably green, which presents a voltage between 1.5 VDC and 3 VDC with 0.03 mA or greater current; an energy storage unit or module (3) connected to the photovoltaic module (1) and which is responsible for storing the energy received by said module (1), wherein the energy storage unit (3) is preferably a battery, which may be of a rechargeable type, although any type of battery is also contemplated within the present invention; a pH meter (not shown), which allows to obtain a pH measurement in the range of 1 to 14, and it is preferably calibrated in 4 or 6; the electrode holder of the present invention previously described, which houses a plurality of electrodes and which is in contact with the energy accumulation unit or module; and an external structure (7) inside which all the previously defined elements are stored, where said external structure (7) is preferably plate-shaped and is the one that comes in direct contact with water, a reason for which it must be manufactured in a neutral material that does not affect the water properties, while at the same time it must be totally hermetic, so as not to allow the entry of water to come into contact with the electrical elements (photovoltaic module (1), energy storage unit (3), etc.).

The purifying device (7) has a cavity (16) in its base, into which the electrode holder (6) fits as shown in FIG. 11. The tab (13) of the metal holder (9), comes in contact through the slot (17) with the plate (112) of the purifying device, which is arranged bent around the housing from the inside of the purifying device (7), outwardly in the cavity (16) of junction with the electrode holder (6). The plate (112) is connected to the negative pole of the energy storage unit or module (3), connecting said storage unit or module with the metal holder (9) and the electrodes of the electrode holder. In turn, the positive pole of the accumulation unit or module is connected to a metal element (113) on the outside of the purifying device, which comes into contact with the water. Thus, an oxide-reduction reaction is started, which allows the release of ions from the electrodes housed in the metal holder into the water. Also, in the upper wall of the cavity (16) there are two slots arranged, in which the tabs (12) of the electrode holder (6) base (8) fit to hold the electrode holder (6) fastened to the purifying device (7).

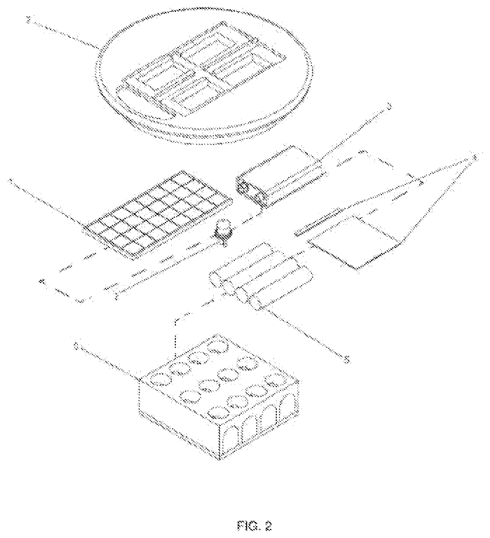

In another embodiment of the purifying device, the electrode holder may be connected with the negative pole of the electrical power source in the cavity (16) by means of a set of two plates (4), as illustrated in FIG. 2.

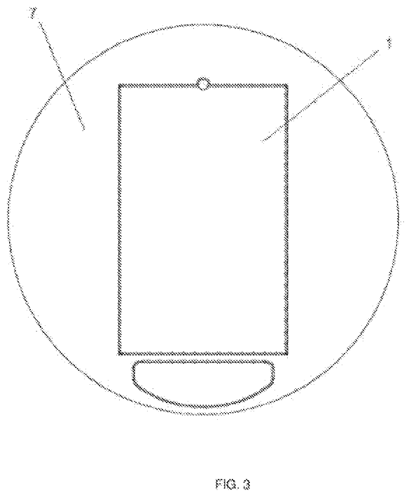

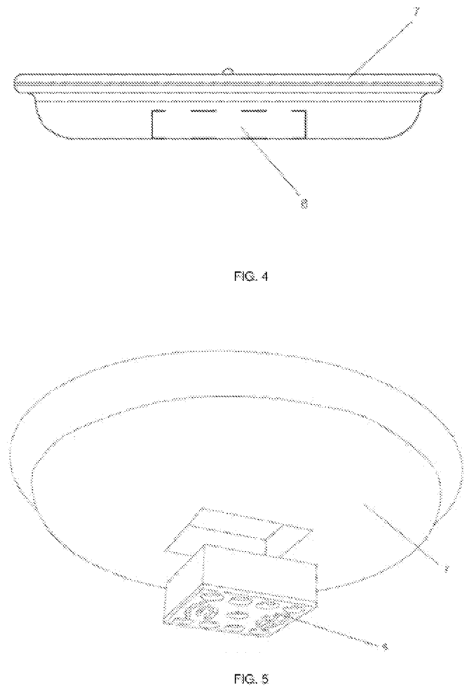

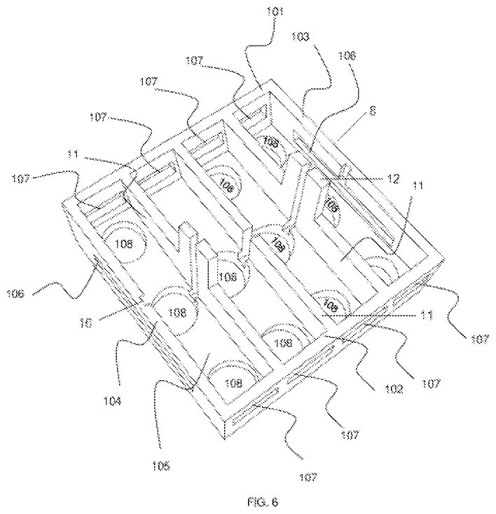

Thus, the floating device is a polymeric material artifact, preferably disc type, as illustrated more clearly in FIG. 3, which has attached in its upper part a photovoltaic solar plate (1) of sufficient voltage and milli-amperage necessary to obtain an electrolytic and electrochemical effect between the metallic alloy electrodes (5), thus dispersing by means of a plastic inner grid the metallic ionic particles to the water, this way obtaining the purification thereof.

By employing an energy accumulation unit or module, when the floating device operates with a solar panel, it may continue providing a purifying effect at times of the day when there is insufficient solar radiation to generate sufficient energy flow for these purposes. In particular, the accumulation unit or module allows the device to have energy autonomy for all its elements during the day and at night, regardless of the lack of solar radiation. With this module, it is ensured that ions continue to be released at night, when there is no longer solar radiation to generate electrical energy in the photovoltaic module.

On the other hand, the electrode holder and device of the present invention is designed, but not limited, to obtain a cleaning of approximately 500 gallons of water per electrode, while having an average life span of 6-12 months per electrode. In addition, its design allows for zero or null cost of chemicals, cleaning and energy, which makes it an environmentally friendly device with continuous operation, while its materials provide excellent buoyancy in all types of water bodies, especially swimming pools.

One of the main advantages of the electrode holder (and thus of the present invention device) and its operation based on dispersion of ions in water, is its non-corrosive and harmless nature, while being more efficient than the normally used chlorine in water purification, softening it by removing iron and calcium, and thus prolonging the life span of the physical infrastructure such as filter tiles, motors, piping in case of water bodies for recreational purposes, such as a swimming pool.

Moreover, the device of the present invention presents the advantage that it is economical and uses resins and elements recovered from other processes in its manufacture, due to its materials, and in addition, it takes advantage of solar energy ensuring a good water quality, improving the users' costs and health, while making the use of conventional electrical power optional, so no permanent wires are required for its power supply and it may be left floating in the water body in a free-floating manner.

In a preferred invention embodiment, the electrodes (5) are manufactured from copper, zinc, silver, gold or stainless-steel coated copper core, and/or minerals, without limitation, wherein the same are composed of 25% to 100% of each of the aforesaid materials for each case.

Similarly, in a preferred manner, the electrode holder element (6) may be loaded with any combination of electrodes (5), i.e., any type of electrode (5) of any material may be placed in said electrode holder (6), wherein there are the following preferred combinations, but wherein the present invention scope is not limited to the same: Copper-Zinc-Silver; Copper-Zinc-Gold; Copper-Silver; Zinc-Silver; Copper-Gold; Zinc-Gold; Copper-Copper-Copper-Copper; Copper-Copper-Copper-Zinc; Copper-Copper-Zinc-Zinc; Copper-Zinc-Zinc-Zinc; Zinc-Zinc-Zinc-Zinc; Copper-Copper-Silver-Zinc; Copper-Silver-Silver-Zinc; Copper-Silver-Silver-Silver; Copper-Copper-Silver-Silver; Silver-Silver-Silver-Silver; Zinc-Zinc-Zinc-Silver; Zinc-Zinc-Silver-Silver; Zinc-Silver-Silver-Silver; Silver-Silver-Silver-Silver; Stainless-steel-Copper.

Accordingly, it is important to note that in any of the aforementioned alloys containing gold, a percentage of gold at 99% purity, i.e., 24 karat gold is desired.

Thus, the materials defined above are highly important and relevant to the present invention, since the products of the reaction are copper ions or zinc ions which have the characteristic of precipitating the algae present in the water, said process is called flocculation, while the production of silver ions or gold ions have an antibacterial and antiviral effect in the water, where said process is called disinfection, on the other hand, a water softening effect is obtained when the electronegative charge of the stainless-steel electrically charges the iron and calcium particles, precipitating them for subsequent filtering, thus obtaining a device with a simultaneous double effect.

In an alternate embodiment, the material from which the electrodes (5) are made may be the aforementioned metals, as well as metallic alloys, including minerals encapsulated in said electrodes (5), such as quartz, activated carbon and others.

The description made heretofore corresponds to one or more embodiments of the present invention and it is not, nor pretends to be, in any way limiting the present application scope, according as set forth and defined in the accompanying claims set.

1. An electrode holder (6), comprising
a base (8);
a metal holder (9) in which one or more electrodes (110) are embedded; and
a cover (10);
wherein the metallic holder is coupled to the interior of the base, the electrodes being housed within the base (8) and under the cover (10), the base (8) being coupled to the cover (10), and the metallic holder being in connection with the negative pole of an electricity source and the positive pole of the electricity source being in connection with an external metallic element.

2. The electrode holder (6) according to claim 1, wherein the base (8) is disposed at the bottom of the electrode holder (6), and comprises five walls including a front wall (101), an opposite rear wall (102), a right wall (103), an opposite left wall (104), and a bottom wall (105), forming a cavity, wherein divisions (11) are arranged parallel to the opposite right (103) and left walls (104), forming a plurality of channels, each housing one electrode of the plurality of electrodes (5) embedded in the metal holder (9); wherein
the right wall (103) and the left wall (104) each comprise end-to-end holes (106);
the front wall (101) and the opposite rear wall (102) comprise holes (107) which are arranged across the width of each of the plurality of channels;
the bottom wall (105) comprises holes (108) along the base of the channels;
in the central zone of each of the divisions (11), and of the right wall (103) and the left wall (104) opposite each other, a perpendicular cavity (16) is arranged, in which the metal holder (9) fits into which the plurality of electrodes is embedded; and
one or more of the divisions (11) comprise tabs (12), which protrude towards the top of the base and engage the cover (10).

3. The electrode holder (6) according to claim 1, wherein the metal holder (9) has a rectangular shape and comprises holes (109) and a tab in the central part (13), protruding towards the top of the holder, wherein through each of the holes (109) an electrode of the plurality of electrodes is embedded under pressure.

4. The electrode holder (6) according to claim 1, wherein the cover (10) is disposed on the top of the electrode holder (6), and comprises a plurality of holes (111) and a plurality of slots (14) into which tabs (12) of the base (8) fit, and a slot (15) into which a tab (13) of the holder (9) fits.

5. The electrode holder (6) according to claim 1, wherein the electrodes are made of a material which is selected from the group consisting of copper, zinc, silver, gold, stainless-steel and combinations thereof.

6. The electrode holder (6) according to claim 1, wherein the electrodes (5) further comprise metal alloys with encapsulated minerals.

7. A floating ionic water purifying device, comprising
a photovoltaic module;
an energy storage module (3) connected to the photovoltaic module (1);
a pH meter;
an electrode holder (6) coupled to a cavity (16) in the base of the device, comprising
a base (8);
a metal holder (9) in which a plurality of electrodes (110) is embedded; and
a cover (10);
wherein the metal holder is coupled to the inside of the base, the electrodes being housed inside the base (8) and under the cover (10), the base being (8) coupled to the cover (10), and the metal holder being in connection with the negative pole of the energy storage module (3) and the positive pole of the energy storage module being in connection with an outer metal element (113); and
an external structure (7) inside which all the elements of the device are stored.

8. The device according to claim 7, further comprising one or more light indicator elements (2).

9. The device in accordance with claim 7, wherein
the base (8) of the electrode holder (6) is disposed at the bottom of the electrode holder (6), and comprises five walls including a front wall (101), an opposite rear wall (102), a right wall (103), an opposite left wall (104), and a bottom wall (105), forming a cavity, wherein divisions (11) are arranged parallel to the opposite right (103) and left (104) walls, forming a plurality of channels, each housing one electrode of the plurality of electrodes (5) embedded in the metal holder (9);
wherein
the right wall (103) and the left wall (104) each comprise end-to-end holes (106);
the front wall (101) and the opposite rear wall (102) comprise holes (107) which are arranged across the width of each of the plurality of channels;
the bottom wall (105) comprises holes (108) along the base of the channels;
in the central zone of each of the divisions (11), and of the right wall (103) and the left wall (104) opposite to each other, a perpendicular cavity (16) is arranged in which the metal holder (9) fits, into which the plurality of electrodes is embedded; and
one or more of the divisions (11) comprise tabs (12), which protrude towards the top of the base and engage the cover (10).

10. The device according to claim 7, wherein the metal holder (9) has a rectangular shape and comprises holes (109) and a tab in the central part (13), protruding towards the top of the holder, wherein through each of the holes (109) an electrode of the plurality of electrodes is embedded under pressure and the tab (13) being in connection with the negative pole of the energy accumulation module (3).

11. The device according to claim 7, wherein the cover (10) is arranged on the top of the electrode holder (6), and comprises a plurality of holes (111) and a plurality of slots (14) into which tabs (12) of the base (8) fit, and a slot (15) into which a tab (13) of the holder (9) fits.

12. The device according to claim 7, wherein the electrodes are made of a material which is selected from the group consisting of copper, zinc, silver, gold, copper, stainless-steel and combinations thereof.

13. The device according to claim 7, wherein the electrodes (5) further comprise metal alloys with encapsulated minerals.

14. The device according to claim 10, wherein the tab (13) of the metal holder (9) is in connection with the negative pole of the energy storage module (3) through a plate (112) which is arranged bent from the inside towards the outside of the device, through a slot (17) in the cavity (16) of the device base.

15. The device according to claim 9, wherein in the cavity (16) of the device base two slots are arranged into which the tabs (12) of the electrode holder base fit.
